(19) United States
(12) Patent Application Publication
(10) Pub. No.: US 2026/0324266 A1
(43) Pub. Date: Oct. 15, 2026

(54) DISPLAY SUBSTRATE, DISPLAY MODULE, AND DISPLAY DEVICE

(71) Applicants: Yunnan Invensight Optoelectronics Technology Co., Ltd., Kunming, Yunnan (CN); BOE Technology Group Co., Ltd., Beijing (CN)

(72) Inventors: Junbo WEI, Beijing (CN); Qingshan SHAN, Beijing (CN); Pengcheng LU, Beijing (CN); Junyan YANG, Beijing (CN); Shengji YANG, Beijing (CN); Yinhu HUANG, Beijing (CN); Yuanlan TIAN, Beijing (CN)

(21) Appl. No.: 18/880,855

(22) PCT Filed: May 16, 2024
(86) PCT No.: PCT/CN2024/093595

§ 371 Date: Jan. 3, 2025

(30) Foreign Application Priority Data
Jun. 1, 2023 (CN) 202310645185.0

(51) Int. Cl. H10K 59/80; H10K 59/35

(52) U.S. Cl. CPC H10K 59/879; H10K 59/353

(57) ABSTRACT

A display substrate, a display module, and a display device. The display substrate comprises a display area and a non-display area located on the periphery of the display area, wherein the non-display area comprises a transition area close to the display area and an edge area away from the display area; the display area and the transition area each comprise a plurality of light-emitting elements arranged on a substrate, a second planarization layer arranged on the sides of the plurality of light-emitting elements away from the substrate, and a plurality of first lenses arranged on the surface of the second planarization layer away from the substrate; the distance between every two adjacent first lenses is D1, and the sag of each first lens is L1.

### CROSS-REFERENCE TO RELATED APPLICATION

The present application is a U.S. National Phase Entry of International Application No. PCT/CN2024/093595 having an international filing date of May 16, 2024, which claims priority to Chinese Patent Application No. 202310645185.0, filed to the CNIPA on Jun. 1, 2023, and entitled “Display Substrate, Display Module, and Display Device”. Contents of the above-identified applications are incorporated herein by reference.

### TECHNICAL FIELD

Embodiments of the present disclosure relate to the field of display technologies, and particularly relate to a display substrate, display module and a display device.

### BACKGROUND

Micro Organic light emitting Diode (Micro-OLED) is a micro-display developed in recent years, and silicon-based OLED is one of them. The silicon-based OLED has advantages such as small size and high resolution, and is manufactured by mature complementary metal oxide semiconductor (CMOS) integrated circuit technology. It can not only realize active addressing of pixels, but also realize manufacturing of a pixel driving circuit, a timing control (TCON) circuit, an overcurrent protection (OCP) circuit, and the like on a silicon-based substrate, which is conducive to reducing a system volume and realize lightweight. The silicon-based OLED is widely used in virtual reality (VR), augmented reality (AR) and other near-eye display fields, such as AR/VR head-mounted display devices.

### SUMMARY

The following is a summary of subject matters described herein in detail. This summary is not intended to limit the protection scope of claims.

An embodiment of the present disclosure provides a display substrate including a display region and a non-display region located at a periphery of the display region. The non-display region includes a transition region close to the display region and an edge region away from the display region.

The display region and the transition region each include a plurality of light emitting elements disposed on a base substrate, a second planarization layer disposed on a side of the plurality of light emitting elements away from the base substrate, and a plurality of first lenses disposed on a surface of the second planarization layer away from the base substrate. The light emitting elements of the display region are configured to be able to emit light, and the light emitting elements of the transition region are not configured to emit light. A spacing between two adjacent first lenses is D1, and an arch height of the first lenses is L1.

The edge region includes a second planarization layer and a lens layer disposed on a surface of the second planarization layer away from the base substrate; and a surface of the second planarization layer of the edge region away from the base substrate protrudes from a surface of the second planarization layer of the display region and the transition region away from the base substrate.

The lens layer has an integral structure and a surface of the lens layer away from the base substrate is planar, or the lens layer includes a plurality of second lenses.

A thickness of the lens layer is L2, and a distance between an edge of the lens layer close to the transition region and an edge of the first lenses close to the edge region in a direction parallel to the base substrate is d2, wherein L2/d2<L1/D1.

An embodiment of the present disclosure also provides a display module, including the display substrate described above.

An embodiment of the present disclosure further provides a display device including the display substrate described above.

Other aspects of the present disclosure may be comprehended after the drawings and the detailed descriptions are read and understood.

### BRIEF DESCRIPTION OF DRAWINGS

Accompanying drawings are intended to provide a further understanding of technical solutions of the present disclosure and form a part of the specification, and are used to explain the technical solutions of the present disclosure together with embodiments of the present disclosure, but do not form limitations on the technical solutions of the present disclosure. Shapes and sizes of components in the drawings do not reflect actual scales, and are only intended to schematically illustrate contents of the present disclosure.

FIG. 1 is a schematic structural diagram of a display module according to some exemplary embodiments.

FIG. 2 is a schematic diagram of a film layer structure and structure of a cover plate of a display substrate of the display module of FIG. 1 according to some exemplary embodiments.

FIG. 3 is a schematic diagram of a planar structure of a display substrate and a cover plate of the display module of FIG. 1 according to some exemplary embodiments.

FIG. 4a is a schematic diagram of a structure of partial film layers of a display substrate of some techniques.

FIG. 4b is a schematic diagram of a display defect of a display module of some techniques.

FIG. 5 is a schematic diagram of a partial cross-sectional structure of a display module according to some exemplary embodiments.

FIG. 6 is a schematic diagram of a planar structure of a display module according to some exemplary embodiments.

FIG. 7 is a schematic diagram of a partial cross-sectional structure of a display module according to some exemplary embodiments.

FIG. 8 is a schematic diagram of a partial cross-sectional structure of a display module according to some exemplary embodiments.

FIG. 9 is a schematic diagram of a partial cross-sectional structure of a display module according to some other exemplary embodiments.

### DETAILED DESCRIPTION

Those of ordinary skills in the art should understand that modifications or equivalent replacements may be made to the technical solutions of the embodiments of the present disclosure without departing from the spirit and scope of the technical solutions of the embodiments of the present disclosure, and should all fall within the scope of the claims of the present disclosure.

As shown in FIG. 1, FIG. 1 is a schematic structural diagram of a display module according to some exemplary embodiments. The display module includes a display substrate 1, an external circuit board 2 bonded to the display substrate 1, and a cover plate 3 disposed on a display side of the display substrate 1. An end of the external circuit board 2 is bonded to the display substrate 1, and the other end of the external circuit board 2 may be configured to be connected with an external drive device to provide a drive signal to the display substrate 1 for display. The external circuit board 2 may be a flexible circuit board, a rigid circuit board, a flexible-rigid combined circuit board, or the like.

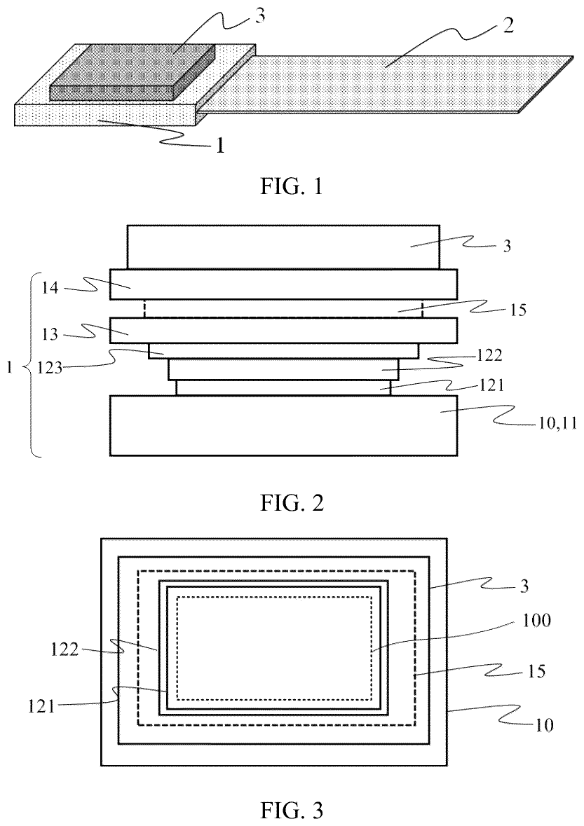

As shown in FIG. 2, FIG. 2 is a schematic diagram of a film layer structure and a structure of a cover plate of a display substrate of the display module of FIG. 1 according to some exemplary embodiments. The display substrate may include a driving backplate 101, and a first electrode 121, a light emitting function layer 122, a second electrode layer 123, a first encapsulation layer 13, a color filter layer 15, and a second encapsulation layer 14 that are sequentially stacked on the driving backplate 101. The driving backplate 101 may include a base substrate and a circuit structure layer disposed on the base substrate. The circuit structure layer includes a pixel driving circuit, and the pixel driving circuit may include multiple transistors and a capacitor. The first electrode 121, the light emitting function layer 122, and the second electrode layer 123 are sequentially stacked to form a light emitting element. The first electrode 121 of the light emitting element may be connected to the pixel driving circuit of the driving backplate 101. A region of the display substrate close to an edge at one side may be provided with a bonding region, the bonding region includes a plurality of bonding pins, and the bonding pins may be configured to be bonded to the external circuit board.

Exemplarily, the display substrate may be a silicon-based OLED display substrate, the base substrate may be a silicon base substrate, and the pixel driving circuit may be manufactured using a CMOS integrated circuit process, and may be manufactured by a 180 nm or 110 nm semiconductor process. The light emitting element may be a white light OLED device and may be a series-type OLED device structure. The first electrode 121 (may be an anode) of the light emitting element may be made of a metal or/and metal oxide material having electrical conductivity and a high work function value. The first electrode 121 may be in a single-layer structure or a multi-layer structure, for example, the first electrode 121 may include a first titanium metal layer, an aluminum or silver metal layer, a second titanium metal layer, and an indium tin oxide (ITO) layer that are sequentially stacked in a direction away from the base substrate. The second electrode layer 123 of the light emitting element may be made of a magnesium-silver alloy or the like. The first encapsulation layer 13 and the second encapsulation layer 14 may be made of one or more of an organic material and an inorganic material having good sealing performance. The inorganic material may be, for example, silicon oxide, silicon nitride, or the like. The first encapsulation layer 13 and the second encapsulation layer 14 may each include a plurality of inorganic material layers that are stacked. The first encapsulation layer 13 and the second encapsulation layer 14 may serve a function of blocking moisture and oxygen, protecting the light emitting element from erosion of water and oxygen. The color filter layer 15 may include multiple filter units capable of transmitting light of a set color, for example, including a red filter unit that transmits red light, a green filter unit that transmits green light, and a blue filter unit that transmits blue light. The white light emitted by each light emitting element passes through a corresponding filter unit and then emits light of a corresponding color, so as to achieve colorized displaying of the display substrate. The cover plate 3 may be provided to cover the display side of the display substrate, and the material of the cover plate 3 may be a material having a high transmittance, for example, glass.

As shown in FIG. 3, FIG. 3 is a schematic diagram of a planar structure of a display substrate and a cover plate of a display module of FIG. 1 in some exemplary embodiments, and the display substrate includes a display region 100 and a non-display region located at a periphery of the display region 100. The cover plate 3 completely covers the display region 100 of the display substrate, and a circumferential edge of the display substrate can protrude from a circumferential edge of the cover plate 3, leaving a certain distance at the periphery of the display substrate without being covered by the cover plate 3, which can be used for positioning and fixing the display module in the complete machine. An orthographic projection of the light emitting function layer 122 on the base substrate 10 may contain orthographic projections of the plurality of first electrodes 121 of the plurality of light emitting elements on the base substrate 10. An orthographic projection of the color filter layer 15 on the base substrate 10 may contain the orthographic projection of the light emitting function layer 122 on the base substrate 10.

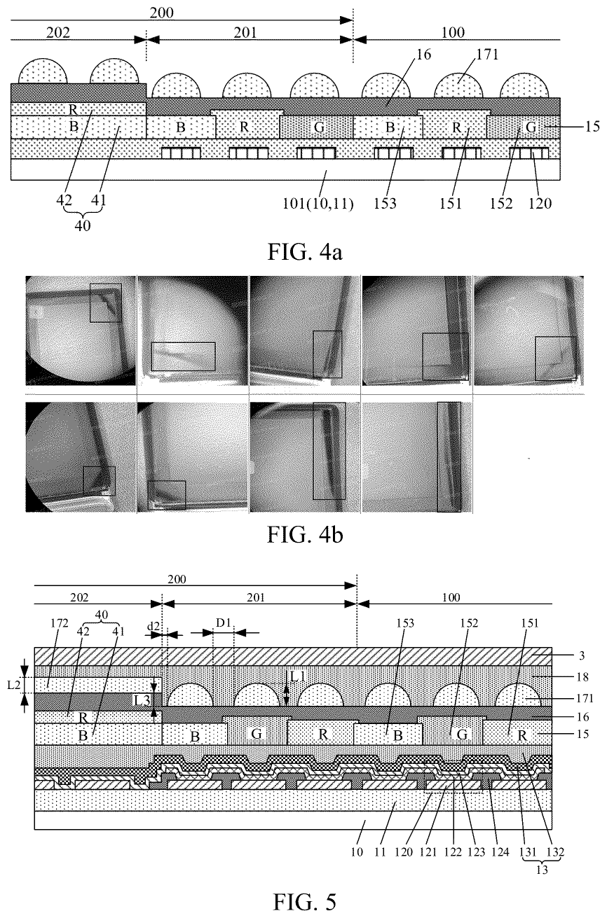

As shown in FIG. 4a, FIG. 4a is a schematic diagram of a structure of partial film layers of a display substrate of some techniques. The display substrate includes a display region 100 and a non-display region 200 located at a periphery of the display region 100, and the non-display region 200 includes a transition region 201 close to the display region 100 and an edge region 202 away from the display region 100. In a direction perpendicular to the display substrate, the display region 100 and the transition region 201 each include a base substrate 10, a circuit structure layer 11 disposed on the base substrate 10 (the base substrate 10 and the circuit structure layer 11 are collectively referred to as a driving backplate 101), a plurality of light emitting elements 120 disposed on the circuit structure layer 11, a color filter layer 15 disposed on a side of the plurality of light emitting elements 120 away from the base substrate 10, and a second planarization layer 16 and a plurality of first lenses 171 sequentially disposed on a side of the color filter layer 15 away from the base substrate 10. The light emitting elements 120 of the display region 100 are configured to be able to emit light, and the light emitting elements 120 of the transition region 201 are not configured to emit light. Each of the first lenses 171 is disposed on a light emitting side of a corresponding light emitting element 120. The color filter layer 15 includes a plurality of filter units. The plurality of filter units includes a plurality of first filter units 151 that transmit light of a first color, a plurality of second filter units 152 that transmit light of a second color, and a plurality of third filter units 153 that transmit light of a third color.

The edge region 202 is provided with at least two color resistance layers (a first color resistance layer 41 and a second color resistance layer 42 are illustrated in the drawings) that are stacked, and a second planarization layer 16 and a plurality of first lenses 171 disposed on a side of the at least two color resistance layers away from the base substrate 10. The stacked at least two color resistance layers of the edge region 202 form a light shielding layer 40 that is light-proof. Each color resistance layer is arranged in the same layer as the first filter unit 151, the second filter unit 152, or the third filter unit 153. The total thickness (thicker) of the at least two color resistance layers of the edge region 202 is inconsistent with the thickness (thinner) of the color filter layer 15 of the display region 100 and the transition region 201, and there will be a height difference at the boundary between the second planarization layer 16 of the edge region 202 and the second planarization layer 16 of the transition region 201. Therefore, in the process of manufacturing the first lenses 171 of the edge region 202, the transition region 201 and the display region 100 on the second planarization layer 16 by the same patterning process, there is a difference in focusing during the exposure process, which leads to insufficient exposure of the edge region 202, and eventually leads to the problems of adhesion between the first lenses 171 of the edge region 202 and the adhesion between the first lenses 171 at the boundary of the edge region 202 and the transition region 201, and further leads to abnormal display in appearance of the display product. As show in FIG. 4b, which is a schematic diagram of a display defect of a display module of some techniques, dark spots in shape of elongate strip and block shape (inside a rectangular frame) appear in the non-fixed regions at the corners of the edge region 202.

When the OLED display device is applied to the near-eye display device, the fixed position of the display panel is very important for the user, which determines the user's experience. On the one hand, the current silicon-based OLED display devices are used in AR/VR devices, and users will appear in different environments, which is crucial to the reliability and life requirements of OLED devices. On the other hand, during the manufacturing process of silicon-based OLED display devices, in order to improve the display effect, there should be no significant color difference on the surface of the module, which results in poor display quality experience.

An embodiment of the present disclosure provides a display substrate. As shown in FIG. 5, which is a schematic diagram of a partial cross-sectional structure of a display module according to some exemplary embodiments, the display substrate includes a display region 100 and a non-display region 200 located at a periphery of the display region 100. The non-display region 200 includes a transition region 201 close to the display region 100 and an edge region 202 away from the display region 100.

The display region 100 and the transition region 201 each include a plurality of light emitting elements 120 disposed on the base substrate 10, a second planarization layer 16 disposed on a side of the plurality of light emitting elements 120 away from the base substrate 10, and a plurality of first lenses 171 disposed on a surface of the second planarization layer 16 away from the base substrate 10. The light emitting elements 120 of the display region 100 are configured to be able to emit light, and the light emitting elements 120 of the transition region 201 are not configured to emit light. A spacing between two adjacent first lenses 171 is D1, and an arch height of the first lenses 171 is L1.

The edge region 202 includes a second planarization layer 16 and a lens layer 172 disposed on a surface of the second planarization layer 16 away from the base substrate 10. A surface of the second planarization layer 16 of the edge region 202 away from the base substrate 10 protrudes from a surface of the second planarization layer 16 of the display region 100 and the transition region 201 away from the base substrate 10.

The lens layer 172 has an integral structure and a surface of the lens layer 172 away from the base substrate 10 is planar. A thickness of the lens layer 172 is L2, and a distance between an edge of the lens layer 172 close to the transition region 201 and an edge of the first lens 171 close to the edge region 202 in a direction parallel to the base substrate 10 is d2, wherein L2/d2<L1/D1.

In the display substrate of the present embodiment, since the lens layer 172 of the edge region 202 and the first lens 171 of the transition region 201 are configured as the following: L2/d2<L1/D1, in the process of fabricating the lens layer 172 and the plurality of first lenses 171 by the same patterning process, it is possible to prevent the problem of adhesion between the lens layer 172 of the edge region 202 and the first lens 171 at the edge of the transition region 201 due to insufficient exposure, and further it is possible to prevent the resulting display defect. In addition, since the lens layer 172 has an integral structure and the surface of the lens layer 172 away from the base substrate 10 is planar, in the process of forming the first lens 171 and the lens layer 172 by the same patterning process, there is no problem of adhesion between a plurality of lenses of the edge region 202 due to insufficient exposure of the edge region 202 in some technologies, thereby improving the display effect, enhancing the competitive advantage of the product, and improving the yield of the product.

In some exemplary embodiments, as shown in FIG. 5, the lens layer 172 and the first lens 171 may be arranged in the same layer.

In some exemplary embodiments, as shown in FIG. 5, L2/L1<0.8 may be configured.

In some exemplary embodiments, as shown in FIG. 5, the display region 100 and the transition region 201 both further include a color filter layer 15 located between the plurality of light emitting elements 120 and the second planarization layer 16, and the color filter layer 15 includes a plurality of filter units. The plurality of filter units includes a plurality of first filter units 151 that transmit light of a first color, a plurality of second filter units 152 that transmit light of a second color, and a plurality of third filter units 153 that transmit light of a third color. Each of the first lenses 171 is provided corresponding to one of the filter units and one of the light emitting elements 120.

The edge region 202 further includes a light shielding layer 40 disposed on a side of the second planarization layer 16 facing the base substrate 10, and the light shielding layer 40 may include at least two color resistance layers that are stacked. The color resistance layers are arranged in the same layer as the first filter unit 151, the second filter unit 152, or the third filter unit 153.

“A and B are arranged in the same layer” herein means that A and B are formed simultaneously through the same patterning process from the same thin film. A “patterning process” herein includes processing such as photoresist coating, mask exposure, development, etching, and photoresist stripping..

In this embodiment, the light shielding layer 40 of the edge region 202 includes at least two color resistance layers that are stacked, and the color resistance layers are arranged in the same layer as the first filter unit 151, the second filter unit 152, or the third filter unit 153. Therefore, during the manufacturing process of the display substrate, in the process of forming some kind of filter units of the color filter layers 15 of the display region 100 and the transition region 201 (a plurality of filter units that transmit the same color light are the same kind of filter units), corresponding color resistance layers can be formed simultaneously in the edge region 202, whereby the light shielding layer 40 can be formed by at least two color resistance layers that are stacked, and the mask and production cost can be saved. The light shielding layer 40 of the edge region 202 can function as a light shield and prevent light leakage at the edge of the display substrate.

In some exemplary embodiments, as shown in FIG. 5, the light shielding layer 40 may include a first color resistance layer 41 and a second color resistance layer 42 sequentially stacked in a direction away from the base substrate 10. The first color resistance layer 41 may be arranged in the same layer as one of the first filter unit 151, the second filter unit 152, and the third filter unit 153, and the second color resistance layer 42 may be arranged in the same layer as any one of the other two of the first filter unit 151, the second filter unit 152, and the third filter unit 153.

For example, the first color resistance layer 41 may be arranged in the same layer as the third filter unit 153, and the second color resistance layer 42 may be arranged in the same layer as the first filter unit 151. Alternatively, the first color resistance layer 41 may be arranged in the same layer as the third filter unit 153, and the second color resistance layer 42 may be arranged in the same layer as the second filter unit 152. Alternatively, the first color resistance layer 41 may be arranged in the same layer as the second filter unit 152, and the second color resistance layer 42 may be arranged in the same layer as the first filter unit 151. The first filter unit 151 may be configured to transmit red light, the second filter unit 152 may be configured to transmit green light, and the third filter unit 153 may be configured to transmit blue light.

In another embodiment, the light shielding layer 40 may include a first color resistance layer 41, a second color resistance layer 42, and a third color resistance layer which are sequentially stacked in a direction away from the base substrate 10. The three color resistance layers are arranged in the same layer as the first filter unit 151, the second filter unit 152, and the third filter unit 153, respectively, and in this example, there is no limitation on which of the three filter units each color resistance layer is arranged in the same layer.

In some exemplary embodiments, as shown in FIG. 5, a thickness of the filter unit arranged in the same layer as the second color resistance layer 42 may be larger than a thickness of the second color resistance layer 42, and a thickness of the filter unit arranged in the same layer as the first color resistance layer 41 may be larger than a thickness of the first color resistance layer 41.

The total thickness of the first color resistance layer 41 and the second color resistance layer 42 may be larger than a thickness of the color filter layer 15.

The thickness of the second color resistance layer 42 may be smaller than the thickness of the first color resistance layer 41.

In some exemplary embodiments, as shown in FIG. 5, a thickness of the light shielding layer 40 may be larger than the thickness of the color filter layer 15 of the display region 100 and the transition region 201.

In some exemplary embodiments, as shown in FIG. 5, a height difference between a surface of the second planarization layer 16 of the edge region 202 away from the base substrate 10 and a surface of the second planarization layer 16 of the transition region 201 away from the base substrate 10 is L3. It may be set to L3<L2, and it may be set to 0<L3<1000 Å.

In some exemplary embodiments, as shown in FIG. 5, the display region 100 and the transition region 201 both further include a first encapsulation layer 13 located between the plurality of light emitting elements 120 and the color filter layer 15. The first encapsulation layer 13 extends to the edge region 202, and the first encapsulation layer 13 of the edge region 202 has an overlapping region with the light shielding layer 40.

A second encapsulation layer may be provided between the color filter layer 15 and the second planar layer 16.

In some exemplary embodiments, as shown in FIG. 5, the display region 100 and the transition region 201 each include a circuit structure layer 11, a light emitting structure layer, a first encapsulation layer 13, a color filter layer 15, and a second planarization layer 16, which are sequentially stacked on the base substrate 10. The light emitting structure layer includes the plurality of light emitting elements 120, and the light emitting elements 120 include a first electrode 121, a light emitting function layer 122, and a second electrode layer 123 sequentially stacked in a direction away from the base substrate 10.

The circuit structure layer 11 of the display region 100 may include a plurality of pixel driving circuits disposed on the base substrate 10, and the pixel driving circuit may include a plurality of transistors (T) and a storage capacitor (C). The pixel driving circuits may have a circuit structure such as 3T1C, 5T1C, or 7T1C, which is not limited in the present disclosure. Exemplarily, the display substrate may be a silicon-based OLED display substrate, and the pixel driving circuit may be fabricated using a CMOS (Complementary Metal Oxide Semiconductor) integrated circuit process. The circuit structure layers 11 of the display region 100 and the transition region 201 both include a first planarization layer away from the base substrate 10, the first planarization layer of the display region 100 is provided with a plurality of first vias, and the first vias are configured so that the first electrode 121 formed subsequently is connected to the pixel driving circuit through the first vias.

The light emitting structure layer may include a plurality of first electrodes 121, a pixel definition layer 124, a light emitting function layer 122 and a second electrode layer 123. The plurality of first electrodes 121 are disposed on a surface of the first planarization layer of the circuit structure layer 11 away from the base substrate 10, and the pixel definition layer 124 is disposed on a side of the plurality of first electrodes 121 away from the base substrate 10 and is provided with a plurality of pixel openings. Each of the pixel openings exposes a surface of a corresponding one of the first electrodes 121 away from the base substrate 10. The light emitting function layer 122 and the second electrode layer 123 are sequentially stacked on a side of the plurality of first electrodes 121 away from the base substrate 10. The first electrode 121 (for example, an anode), the light emitting function layer 122, and the second electrode layer 123 (for example, a cathode) form the light emitting element 120.

Exemplarily, the light emitting element 120 may be configured to emit white light. The light emitting function layer 122 may include a first light emitting unit 351, a charge generation layer, and a second light emitting unit that are sequentially stacked in a direction away from the base substrate 10. The first light emitting unit may include a first light emitting layer capable of emitting red light and a second light emitting layer capable of emitting green light, and the second light emitting unit may include a third light emitting layer capable of emitting blue light that are stacked. Thus, under an action of voltages of the first electrodes 121 and the second electrode layer 123, the light emitting element 120 can emit white light through superposition of the light emitted by the first light emitting layer, the light emitted by the second light emitting layer and the light emitted by the third light emitting layer. The plurality of light emitting elements 120 cooperate with the color filter layer 15 to realize color display.

The first encapsulation layer 13 may include one film layer or a plurality of inorganic material layers that are stacked, and the color filter layer 15 may be disposed on a surface of the first encapsulation layer 13 away from the base substrate 10. Exemplarily, the first encapsulation layer 13 may include a first sub-encapsulation layer 131 and a second sub-encapsulation layer 132 sequentially stacked in a direction away from the base substrate 10, and both of the first sub-encapsulation layer 131 and the second sub-encapsulation layer 132 may be inorganic material layers.

A second encapsulation layer (not shown) may be provided between the color filter layer 15 and the second planar layer 16. The second encapsulation layer may include one film layer or a plurality of inorganic material layers that are stacked. The inorganic material of the first encapsulation layer 13 and the second encapsulation layer may be one or more of the followings: silicon oxide (SiO_{X}), silicon nitride (SiN_{X}), and silicon oxynitride (SiO_{X}N_{Y}). The material of the second planarization layer 16 may be an organic material or an inorganic material. The first encapsulation layer 13 and the second encapsulation layer may extend to the edge region 202.

In some examples of the present embodiment, as shown in FIG. 5, the cover plate 3 may be attached to the display side of the display substrate through an adhesive layer 18. The adhesive layer 18 may cover the plurality of first lenses 171 of the display region 100 and the transition region 201, and the lens layer 172 of the edge region 202. The adhesive layer 18 may be formed after the adhesive is cured.

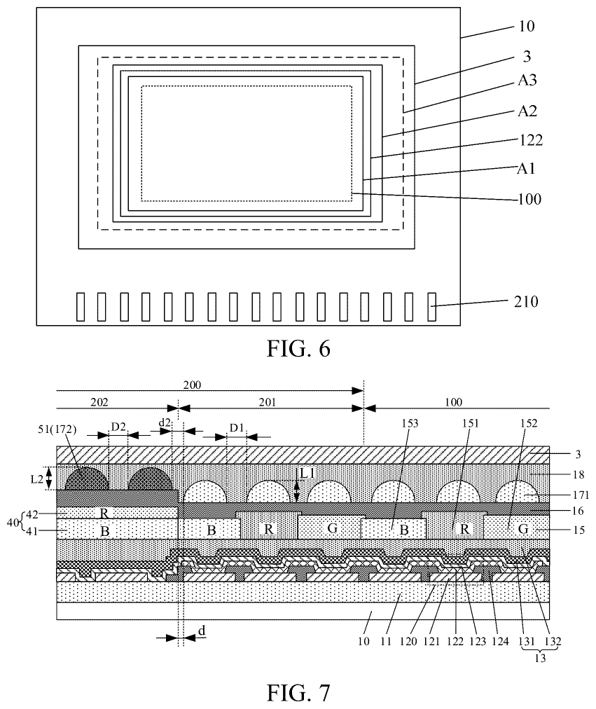

In some exemplary embodiments, as shown in FIGS. 5 and 6, FIG. 6 is a schematic diagram of a planar structure of a display module according to some exemplary embodiments. The edge region 202 of the display substrate includes a bonding region disposed close to an edge at a side of the base substrate 10. The bonding region includes a plurality of bonding pins 210, and the bonding pins 210 can be configured to be bonded to an external circuit board.

A boundary of orthographic projections of the plurality of first electrodes 121 on the base substrate 10 is A1, an orthographic projection of a boundary of the transition region 201 and the edge region 202 on the base substrate 10 is A2, and a boundary of an orthographic projection of the light shielding layer 40 on the base substrate 10 away from the display region 100 is A3. The boundary A1 of the orthographic projections of the plurality of first electrodes 121 on the base substrate 10 may be located outside a boundary of an orthographic projection of the display region 100 on the base substrate 10. An orthographic projection of the light emitting function layer 122 on the base substrate 10 may include the orthographic projections of the plurality of first electrodes 121 on the base substrate 10, and the orthographic projection of the light emitting function layer 122 on the base substrate 10 includes the boundary A1 of the orthographic projections of the plurality of first electrodes 121 on the base substrate 10. The orthographic projection A2 of the boundary of the transition region 201 and the edge region 202 on the base substrate 10 may surround the orthographic projection of the light emitting function layer 122 on the base substrate 10. The boundary A3 of the orthographic projection of the light shielding layer 40 on the base substrate 10 away from the display region 100 may surround the orthographic projection A2 of the boundary of the transition region 201 and the edge region 202 on the base substrate 10. An orthographic projection of the cover plate 3 on the base substrate 10 may include the boundary A3 of the orthographic projection of the light shielding layer 40 on the base substrate 10 away from the display region 100. There is a spacing between the boundary of the orthographic projection of the cover plate 3 on the base substrate 10 and an edge of the display substrate.

In some exemplary embodiments, as shown in FIG. 7, which is a schematic diagram of a partial cross-sectional structure of a display module according to some exemplary embodiments, the display module includes a display substrate and a cover plate 3 disposed on a display side of the display substrate.

The display substrate includes a display region 100 and a non-display region 200 located at a periphery of the display region 100, and the non-display region 200 includes a transition region 201 close to the display region 100 and an edge region 202 away from the display region 100.

The display region 100 and the transition region 201 each include a plurality of light emitting elements 120 disposed on the base substrate 10, a second planarization layer 16 disposed on a side of the plurality of light emitting elements 120 away from the base substrate 10, and a plurality of first lenses 171 disposed on a surface of the second planarization layer 16 away from the base substrate 10. The light emitting elements 120 of the display region 100 are configured to be able to emit light, and the light emitting elements 120 of the transition region 201 are not configured to emit light. A spacing between two adjacent first lenses 171 is D1, and an arch height of the first lenses 171 is L1.

The edge region 202 includes a second planarization layer 16 and a lens layer 172 disposed on a surface of the second planarization layer 16 away from the base substrate 10. A surface of the second planarization layer 16 of the edge region 202 away from the base substrate 10 protrudes from a surface of the second planarization layer 16 of the display region 100 and the transition region 201 away from the base substrate 10.

The lens layer 172 may include a plurality of second lenses 51. A thickness of the lens layer 172 (in this example, an arch height of the second lenses 51) is L2, and a distance between an edge of the lens layer 172 close to the transition region 201 and an edge of the first lenses 171 close to the edge region 202 in a direction parallel to the base substrate 10 is d2, wherein L2/d2<L1/D1.

In the display substrate of the present embodiment, the lens layer 172 includes a plurality of second lenses 51, and the second lenses 51 of the edge region 202 and the first lenses 171 of the transition region 201 are configured as the following: L2/d2<L1/D1. Therefore, in the process of manufacturing the plurality of second lenses 51 and the plurality of first lenses 171 by the same patterning process, it is possible to prevent the problem of adhesion of the second lenses 51 and the first lenses 171 at the boundary between the edge region 202 and the transition region 201 due to insufficient exposure in some techniques, and further it is possible to prevent display failure caused thereby.

In some examples of the present embodiment, as shown in FIG. 7, a spacing between two adjacent second lenses is D2, where it may be set to L2/D2<L1/D1, and it may be set to L2/D2<L2/d2. In this way, in the process of manufacturing the plurality of second lenses 51 and the plurality of first lenses 171 by the same patterning process, it is possible to prevent the problem of adhesion between the second lenses 51 of the edge region 202 due to insufficient exposure in some techniques, and further it is possible to prevent the display failure caused thereby.

In some examples of the present embodiment, as shown in FIG. 7, the spacing between two adjacent second lenses is D2, and it may be set to D2>D1. In this way, in the process of manufacturing the plurality of second lenses 51 and the plurality of first lenses 171 by the same patterning process, it is possible to prevent the problem of adhesion between the second lenses 51 of the edge region 202 due to insufficient exposure in some techniques, and further it is possible to prevent the display failure caused thereby. In addition, in the manufacturing process of the display substrate, the first lenses 171 and the second lenses 51 can be independently manufactured (independently exposed and developed), that is, the first lenses 171 and the second lenses 51 can be independently formed in different patterning processes respectively. Since the spacing D2 between two adjacent second lenses 51 is large, the second lenses 51 are not easily adhered to each other in the patterning process of forming the plurality of second lenses 51.

In some examples of the present embodiment, the spacing D2 between two adjacent second lenses 51 may be 0.6 μm to 0.8 μm. The spacing D1 between two adjacent first lenses 171 of the display region 100 or/and the transition region 201 may be 0.4 μm to 0.6 μm. The arch height of the second lens 51 may be the same as or different from the arch height of the first lens 171. The parameters of the first lens 171 and the second lens 51 may be independently designed.

In some examples of the present embodiment, as shown in FIG. 7, the surfaces of the first lens 171 and the second lens 51 away from the base substrate 10 are spherical surfaces arched in a direction away from the base substrate 10, and a curvature of the first lens 171 may be larger than a curvature of the second lens 51. The first lens 171 of the display region 100 can converge light emitted by the corresponding light emitting element 120 to improve the luminance of the display substrate. The larger the curvature of the first lens 171 is, the better the light convergence effect is.

In some exemplary embodiments, as shown in FIG. 7, a distance between an edge of the light shielding layer 40 close to the transition region 201 and an edge of the first lens 171 close to the edge region 202 in the direction parallel to the base substrate 10 is d. It may be set to d<d2. It may be set to 200 Å<d<1000 Å.

In some exemplary embodiments, as shown in FIGS. 5 and 7, adjacent filter units transmitting light of different colors overlap. The overlapping portions of the adjacent filter units transmitting light of different colors may form a black matrix, which may prevent cross-color between adjacent sub-pixels.

In some examples of the present embodiment, as shown in FIG. 5, in the display region 100 and the transition region 201, a part of at least one of the first filter units 151 is stacked on a side of the third filter unit 153 away from the base substrate 10, and a part of at least one of the second filter units 152 is stacked on a side of the first filter unit 151 away from the base substrate 10. In the process of manufacturing the color filter layer 15, the manufacturing may be arranged in the following sequence: the third filter unit 153, the first filter unit 151, and the second filter unit 152. The first filter unit 151 transmits red light, the second filter unit 152 transmits green light, and the third filter unit 153 transmits blue light.

In some examples of the present embodiment, as shown in FIG. 7, in the display region 100 and the transition region 201, a part of at least one of the second filter units 152 is stacked on a side of the third filter unit 153 away from the base substrate 10, and a part of at least one of the first filter units 151 is stacked on a side of the second filter unit 152 away from the base substrate 10. In the process of manufacturing the color filter layer 15, the manufacturing may be arranged in the following sequence: the third filter unit 153, the second filter unit 152, and the first filter unit 151. The first filter unit 151 transmits red light, the second filter unit 152 transmits green light, and the third filter unit 153 transmits blue light.

In another embodiment, a part of at least one of the second filter units 152 is stacked on a side of the first filter unit 151 away from the base substrate 10, and a part of at least one of the third filter units 153 is stacked on a side of the second filter unit 152 away from the base substrate 10. In the process of manufacturing the color filter layer 15, the manufacturing may be arranged in the following sequence: the first filter unit 151, the second filter unit 152, and the third filter unit 153. The first filter unit 151 transmits red light, the second filter unit 152 transmits green light, and the third filter unit 153 transmits blue light.

In some exemplary embodiments, the edge region 202 may not be provided with a lens layer.

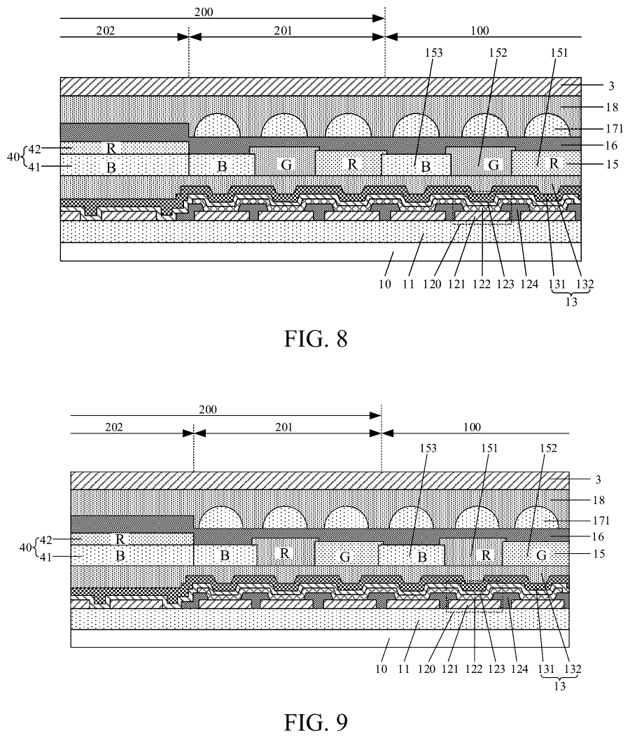

Exemplarily, as shown in FIGS. 8 and 9, FIG. 8 is a schematic diagram of a partial cross-sectional structure of a display module according to some exemplary embodiments and FIG. 9 is a schematic diagram of a partial cross-sectional structure of a display module according to some other exemplary embodiments. The display module includes a display substrate and a cover plate 3 disposed on a display side of the display substrate.

The display substrate includes a display region 100 and a non-display region 200 located at a periphery of the display region 100, and the non-display region 200 includes a transition region 201 close to the display region 100 and an edge region 202 away from the display region 100.

The display region 100 and the transition region 201 each include a plurality of light emitting elements 120 disposed on the base substrate 10, a color filter layer 15 and a second planarization layer 16 sequentially stacked on a side of the plurality of light emitting elements 120 away from the base substrate 10, and a plurality of first lenses 171 disposed on a surface of the second planarization layer 16 away from the base substrate 10. The light emitting elements 120 of the display region 100 are configured to be able to emit light, and the light emitting elements 120 of the transition region 201 are not configured to emit light. The color filter layer 15 includes a plurality of filter units. The plurality of filter units include a plurality of first filter units 151 that transmit light of a first color, a plurality of second filter units 152 that transmit light of a second color, and a plurality of third filter units 153 that transmit light of a third color. The first filter unit 151 may transmit red light, the second filter unit 152 may transmit green light, and the third filter unit 153 may transmit blue light.

The edge region 202 includes a light shielding layer 40 and a second planarization layer 16 sequentially disposed in a direction away from the base substrate 10. A side of the second planarization layer 16 of the edge region 202 away from the base substrate 10 is not provided with a lens layer. A surface of the second planarization layer 16 of the edge region 202 away from the base substrate 10 protrudes from a surface of the second planarization layer 16 of the display region 100 and the transition region 201 away from the base substrate 10.

As show in FIG. 8, in the process of manufacturing the color filter layer 15, the manufacturing may be arranged in the following sequence: the third filter unit 153, the first filter unit 151, and the second filter unit 152. As shown in FIG. 9, in the process of manufacturing the color filter layer 15, the manufacturing may be arranged in the following sequence: the third filter unit 153, the second filter unit 152, and the first filter unit 151.

In the present embodiment, since no lens layer is provided on a side of the second planarization layer 16 of the edge region 202 away from the base substrate 10, there is no problem of lenses adhesion between the lenses of the edge region 202 and at the boundary between the edge region 202 and the transition region 201 in some techniques. Even if the difference between the thickness of the light shielding layer 40 of the edge region 202 and the thickness of the color filter layer 15 of the display region 100 and the transition region 201 is large, the manufacturing process of the first lens 171 will not be affected. Therefore, the manufacturing sequence of the first filter unit 151, the second filter unit 152, and the third filter unit 153 will not affect the manufacturing process of the first lens 171 in the manufacturing process of the color filter layer 15 of the display region 100 and the transition region 201. In this way, the manufacturing sequence of the first filter unit 151, the second filter unit 152, and the third filter unit 153 can be customized according to the customer's needs to match the color shift requirements of the display substrate at different viewing angles and improve the display effect.

An embodiment of the present disclosure further provides a display module. As shown in FIG. 5, the display module includes the display substrate according to any of the above embodiments, and a cover plate 3 provided on a display side of the display substrate. An orthographic projection of the cover plate 3 on the base substrate 10 contains an orthographic projection of the color filter layer 15 on the base substrate 10, and contains an orthographic projection of the light shielding layer 40 on the base substrate 10.

As shown in FIG. 5, the cover plate 3 may be attached to the display side of the display substrate by an adhesive layer 18, and the adhesive layer 18 may be formed after the adhesive is cured.

An embodiment of the present disclosure further provides a display device, which includes the display substrate according to any one of the previous embodiments. The display device may be any product or component with a display function, such as a mobile phone, a tablet computer, a television, a display, a laptop computer, a digital photo frame, and a navigator. Alternatively, the display device may be a near-eye display device, such as AR/VR glasses, a helmet display, a virtual reality all-in-one device and the like.

In the accompanying drawings, a size of a constituent element, and a thickness of a layer or a region are sometimes exaggerated for clarity. Therefore, an implementation of the present disclosure is not necessarily limited to the size, and the shape and size of each component in the drawings do not reflect an actual scale. In addition, the drawings schematically illustrate some examples, and an implementation of the present disclosure is not limited to the shapes or numerical values shown in the drawings.

In the description herein, “parallel” refers to a state in which an angle formed by two straight lines is above −10° and below 10°, and thus includes a state in which the angle is above −5° and below 5°. In addition, “perpendicular” refers to a state in which an angle formed by two straight lines is above 80° and below 100°, and thus includes a state in which the angle is above 85° and below 95°.

In the description herein, orientation or position relationships indicated by the terms “upper”, “lower”, “left”, “right”, “top”, “inside”, “outside”, “axial”, “four corners” and the like are orientation or position relationships shown in the drawings, and are intended to facilitate description of the embodiments of the present disclosure and simplification of the description, but not to indicate or imply that the mentioned structure has a specific orientation or is constructed and operated in a specific orientation, therefore, they should not be understood as limitations on the present disclosure.

In the description herein, unless otherwise specified and defined explicitly, terms “connection”, “fixed connection”, “installation”, and “assembly” should be understood in a broad sense. For example, it may be a fixed connection, a detachable connection, or an integrated connection; terms “installation”, “connection”, and “fixed connection” may be a direct connection, an indirect connection through an intermediary, or communication inside two elements. For those ordinarily skilled in the art, meanings of the above terms in the embodiments of the present disclosure may be understood according to situations.

1. A display substrate, comprising a display region and a non-display region located at a periphery of the display region, wherein the non-display region comprises a transition region close to the display region and an edge region away from the display region;
the display region and the transition region each comprise a plurality of light emitting elements disposed on a base substrate, a second planarization layer disposed on a side of the plurality of light emitting elements away from the base substrate, and a plurality of first lenses disposed on a surface of the second planarization layer away from the base substrate; the light emitting elements of the display region are configured to be able to emit light, and the light emitting elements of the transition region are not configured to emit light; and a spacing between two adjacent first lenses is D1, and an arch height of the first lenses is L1;
the edge region comprises a second planarization layer and a lens layer disposed on a surface of the second planarization layer away from the base substrate; and a surface of the second planarization layer of the edge region away from the base substrate protrudes from a surface of the second planarization layer of the display region and the transition region away from the base substrate;
the lens layer has an integral structure and a surface of the lens layer away from the base substrate is planar, or the lens layer comprises a plurality of second lenses; and
a thickness of the lens layer is L2, and a distance between an edge of the lens layer close to the transition region and an edge of the first lenses close to the edge region in a direction parallel to the base substrate is d2, wherein L2/d2<L1/D1.

2. The display substrate according to claim 1, wherein a spacing between two adjacent second lenses is D2, and wherein L2/D2<L1/D1.

3. The display substrate according to claim 2, wherein L2/D2<L2/d2.

4. The display substrate according to claim 1, wherein a spacing between two adjacent second lenses is D2, and wherein D2>D1.

5. The display substrate according to claim 4, wherein D2 is 0.6 μm to 0.8 μm, and D1 is 0.4 μm to 0.6 μm.

6. The display substrate according to claim 1, wherein the lens layer has an integral structure and the surface of the lens layer away from the base substrate is planar, and wherein L2/L1<0.8.

7. The display substrate according to claim 1, wherein surfaces of the first lenses and the second lenses away from the base substrate are spherical surfaces arched in a direction away from the base substrate, and a curvature of the first lenses is larger than a curvature of the second lenses.

8. The display substrate according to claim 1, wherein the display region and the transition region each further comprise a color filter layer between the plurality of light emitting elements and the second planarization layer, the color filter layer comprises a plurality of filter units, and the plurality of filter units comprise a plurality of first filter units transmitting light of a first color, a plurality of second filter units transmitting light of a second color, and a plurality of third filter units transmitting light of a third color; and
the edge region further comprises a light shielding layer disposed on a side of the second planarization layer facing the base substrate, the light shielding layer comprises at least two color resistance layers that are stacked, and the color resistance layers are arranged in the same layer as the first filter units, the second filter units, or the third filter units.

9. The display substrate according to claim 8, wherein the light shielding layer comprises a first color resistance layer and a second color resistance layer sequentially stacked in a direction away from the base substrate; the first color resistance layer is arranged in the same layer as one of the first filter units, the second filter units, and the third filter units, and the second color resistance layer is arranged in the same layer as any of the other two of the first filter units, the second filter units, and the third filter units.

10. The display substrate according to claim 9, wherein a thickness of the filter unit arranged in the same layer as the second color resistance layer is larger than a thickness of the second color resistance layer, and a thickness of the filter unit arranged in the same layer as the first color resistance layer is larger than a thickness of the first color resistance layer.

11. The display substrate according to claim 10, wherein a total thickness of the first color resistance layer and the second color resistance layer is larger than a thickness of the color filter layer.

12. The display substrate according to claim 9, wherein a thickness of the second color resistance layer is smaller than a thickness of the first color resistance layer.

13. The display substrate according to claim 8, wherein a thickness of the light shielding layer is larger than a thickness of the color filter layer of the display region and the transition region.

14. The display substrate according to claim 1, wherein a height difference between a surface of the second planar layer of the edge region away from the base substrate and a surface of the second planar layer of the transition region away from the base substrate is L3, and L3<L2.

15. The display substrate according to claim 14, wherein 0<L3<1000 Å.

16. The display substrate according to claim 8, wherein a distance between an edge of the light shielding layer close to the transition region and an edge of the first lenses close to the edge region in the direction parallel to the base substrate is d, and d<d2.

17. The display substrate according to claim 8, wherein the first filter units transmit red light, the second filter units transmit green light, and the third filter units transmit blue light; adjacent filter units transmitting light of different colors overlap;
a part of at least one of the first filter units is stacked on a side of the third filter units away from the base substrate, and a part of at least one of the second filter units is stacked on a side of the first filter units away from the base substrate;
or, a part of at least one of the second filter units is stacked on a side of the third filter units away from the base substrate, and a part of at least one of the first filter units is stacked on a side of the second filter units away from the base substrate;
or, a part of at least one of the second filter units is stacked on a side of the first filter units away from the base substrate, and a part of at least one of the third filter units is stacked on a side of the second filter units away from the base substrate.

18. The display substrate according to claim 8, wherein the display region and the transition region each further comprise a first encapsulation layer between the plurality of light emitting elements and the color filter layer; the first encapsulation layer extends to the edge region, and the first encapsulation layer of the edge region has an overlapping region with the light shielding layer.

19. A display module, comprising the display substrate according to claim 8, and a cover plate disposed on a display side of the display substrate; an orthographic projection of the cover plate on the base substrate contains an orthographic projection of the color filter layer on the base substrate and contains an orthographic projection of the light shielding layer on the base substrate.

20. A display device, comprising the display substrate according to claim 1.
